(19) United States
(12) Patent Application Publication
(10) Pub. No.: US 2010/0176478 A1
(43) Pub. Date: Jul. 15, 2010

(54) SEMICONDUCTOR DEVICE AND METHOD FOR MANUFACTURING THE SAME

(75) Inventors: Akira Toriumi, Bunkyo-ku (JP); Tomonori Nishimura, Bunkyo-ku (JP)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: THE UNIVERSITY OF TOKYO, Bunkyo-ku, Tokyo (JP)

(21) Appl. No.: 12/676,353

(22) PCT Filed: Sep. 1, 2008
(86) PCT No.: PCT/JP2008/065688

§ 371 Date: Mar. 3, 2010

(30) Foreign Application Priority Data
Sep. 3, 2007 (JP) 2007-227480

(51) Int. Cl. H01L 29/06; H01L 21/30

(52) U.S. Cl. 257/472; 438/584; 257/E21.211; 257/E29.005

(57) ABSTRACT

Provided are a novel method and a novel structure for bringing a Ge or SiGe compound and a metal into ohmic contact with each other. A semiconductor device is provided with a portion composed of only i) Ge or SiGe compound, ii) a metal, and iii) an insulator or a semiconductor arranged between the material i) and the metal ii). In the semiconductor device, A) the material i) and the metal ii) have Schottky junction in the case where the holes of the material i) are majority carriers, and/or B) the material i) and the metal ii) are in an ohmic contact when the electrons of the material i) are majority carriers.

### TECHNICAL FIELD

The present invention relates to a semiconductor device comprising a portion consisting of i) Ge or an SiGe compound (in particular, Ge); ii) a metal; and iii) an insulator or a semiconductor (in particular, an insulator) arranged between i) the substance and ii) the metal, and a method for manufacturing the semiconductor device.

### BACKGROUND ART

When Ge is brought into contact with a metal, a Schottky junction is always confirmed irrespective of a work function of the metal, with which Ge is brought into contact, in a case where Ge is of an n type. In contrast, an ohmic contact is confirmed in a case where Ge is of a p type (see Non-Patent Document 1 or 2).

Therefore, the same technique as that for use in Si can be used so as to achieve an ohmic contact between n type Ge and a metal. In other words, impurities are introduced into Ge by ion implantation or the like, and then, a portion having impurities at a high concentration is brought into contact with a metal, thereby to achieve the ohmic contact between the n type Ge and the metal.

Non-Patent Document 1: A. Dimoulas et al., Appl. Phys. Lett. 89, 252110 (2006).

Non-Patent Document 2: T. Nishimura et al., Ext. Abs.

### DISCLOSURE OF INVENTION

### Problem to be Solved by the Invention

However, there has already arisen a problem with regard to Si that resistance of a semiconductor impurity layer is markedly higher than that of a metal so that the impurity layer or a contact resistance limits the performance of a transistor per se. This impairs the merit of high performance based on recent fineness techniques. Although Ge is superior to Si with regard to the property of a semiconductor per se, its advantage cannot be appreciated in a case where the above-described portion limits the performance of the transistor.

An object of the present invention is to solve the above-described problem.

Specifically, an object of the present invention is to provide a novel technique and a novel structure, in which

A) in a case where holes of Ge (or an SiGe compound) are majority carriers, a substance and a metal have a Schottky junction; and/or

B) in a case where electrons of Ge (or an SiGe compound) are majority carriers, the substance and the metal are brought into ohmic contact with each other.

### Means for Solving Problems

The present inventors have earnestly studied in order to achieve the above-mentioned objects, and have found the following inventions:

<1> A semiconductor device comprising a portion consisting of i) Ge or an SiGe compound; ii) a metal; and iii) an insulator or a semiconductor arranged between i) the substance and ii) the metal,

wherein A) in a case where holes of i) the substance are majority carriers, i) the substance and ii) the metal have a Schottky junction; and/or

B) in a case where B) electrons of i) the substance are majority carriers, i) the substance and ii) the metal are brought into ohmic contact with each other.

<2> In the above item <1>, iii) the substance may be an insulator having a thickness of 2.5 nm or less, preferably 2.2 nm or less.

<3> A semiconductor device comprising a portion consisting of i) Ge or an SiGe compound; ii) a metal; and iii′) an insulator arranged between i) the substance and ii) the metal, iii′) the insulator having a thickness of 2.5 nm or less, preferably 2.2 nm or less.

<4> In any one of the above items <1> to <3>, wherein i) the substance may be Ge.

<5> In any one of the above items <1> to <4>, the insulator may be selected from the group consisting of oxides, nitrides, sulfides, and compounds thereof.

<6> A method for manufacturing a semiconductor device, the semiconductor device comprising a portion consisting of i) Ge or an SiGe compound; ii) a metal; and iii) an insulator or a semiconductor arranged between i) the substance and ii) the metal,

wherein A) in a case where holes of i) the substance are majority carriers, i) the substance and ii) the metal have a Schottky junction; and/or

B) in a case where B) electrons of i) the substance are majority carriers, i) the substance and ii) the metal are brought into ohmic contact with each other,

the method comprising the steps of:

a) preparing i) the substance;

b) arranging iii) the substance directly on a surface of i) the substance; and

c) arranging ii) the metal directly on a surface of iii) the substance.

<7> In the above item <6>, iii) the substance may be an insulator, and the step b) may be carried out such that iii) the insulator may have a thickness of 2.5 nm or less, preferably 2.2 nm or less.

<8> A method for manufacturing a semiconductor device, the semiconductor device comprising a portion consisting of i) Ge or an SiGe compound; i) a metal; and iii′) an insulator arranged between i) the substance and ii) the metal, iii′) the insulator having a thickness of 2.5 nm or less, preferably 2.2 nm or less,

the method comprising the steps of:

a) preparing i) the substance;

b′) arranging iii′) the insulator directly on a surface of i) the substance; and

c′) arranging ii) the metal directly on a surface of iii′) the insulator.

<9> In any one of the above items <6> to <8>, i) the substance may be Ge.

<10> In any one of the above items <6> to <9>, the insulator may be selected from the group consisting of oxides, nitrides, sulfides, and compounds thereof.

### EFFECTS OF THE INVENTION

The present invention can provide a novel technique and a novel structure, in which

A) in a case where holes of Ge (or an SiGe compound) are majority carriers, a substance and a metal have a Schottky junction; and/or

B) in a case where electrons of Ge (or an SiGe compound) are majority carriers, the substance and the metal are brought into ohmic contact with each other

### BEST MODES FOR CARRYING OUT THE INVENTION

The present invention will be described in detail hereinafter.

The present invention provides a semiconductor device comprising a portion consisting of i) Ge or an SiGe compound; ii) a metal; and iii) an insulator or a semiconductor, in particular, a semiconductor arranged between i) the substance, in particular, Ge and ii) the metal. In particular, the present invention provides a semiconductor device, in which

A) in a case where holes of Ge (or an SiGe compound) are majority carriers, substance and a metal have a Schottky junction; and/or

B) in the case where electrons of Ge (or an SiGe compound) are majority carriers, substance and a metal are brought into ohmic contact with each other, in the above-described portion.

Upon inventing the present invention, the present inventors found the followings: when Ge and a metal are brought into direct contact with each other, an ohmic contact is achieved x) in a case where Ge is of a p type: while a Schottky junction is always achieved irrespective of a work function of the metal y) in a case where Ge is of a n type; and Ge cannot be used in various kinds of semiconductor devices z) in a case where the n type Ge and the metal always have the Schottky junction.

In view of this, the inventors have found a scheme such that Fermi Level Pinning (FLP) occurring at the Ge/metal junction can be suppressed by arranging an insulator between Ge and the metal, thereby to achieve the ohmic contact between Ge and the metal. More specifically, the inventors have found following scheme: Arrangement of an insulator between Ge and the metal results in that A) in a case where holes of Ge are majority carriers, the substance and the metal have a Schottky junction; and/or B) in a case where electrons of Ge are majority carriers, the substance and the metal are brought into ohmic contact with each other.

The same phenomenon can be found with respect to not only Ge but also a SiGe compound. In addition, the same phenomenon can be found also when not an insulator but a semiconductor is arranged between Ge and the metal.

According to the present invention, i) Ge or the SiGe compound may be used. Although the contents of Ge in the SiGe compound are not particularly limited as long as the SiGe compound has characteristics approximate to those of Ge, Ge may be preferably 80 at % or more on the assumption that the total atomic amount of Si and Ge in the SiGe compound is 100 at %. The substance i) may be preferably Ge.

According to the present invention, ii) the metal means an electron conducting substance, and may include pure metals such as Au, Ag, Cu and the like; electron conductive compounds such as PtSiₓ, NiGeₓ, TiN and the like; and electron conductive alloys such as MoTa, TiAl and the like.

According to the present invention, iii) the substance constructing the portion may be an insulator or semiconductor, as described above, and preferably an insulator.

The substance iii) constructing the portion may have a thickness enough that A) i) the substance, i.e., Ge or the SiGe compound and ii) the metal have a Schottky junction in a case where holes of Ge are majority carriers; and/or B) the substance and the metal are brought into ohmic contact with each other in a case where electrons of Ge are majority carriers.

In a case where iii) the substance is an insulator, its thickness may be preferably thinner if the effects A) and/or B) is produced. The thickness, depending on the substance constituting the insulator, may be 2.5 nm or less, more preferably, 2.2 nm or less. Furthermore, the minimum thickness of the insulator, depending on the substance constituting the insulator, may be enough to form a monomolecular layer on a surface of i) the substance, that is, on a surface of Ge or the SiGe compound, or on a surface of ii) the metal.

According to the present invention, the thickness of the insulator is determined by a grazing incident X-ray reflectivity measurement method. As for the grazing incident X-ray reflectivity measurement method, see Literature: H. Shimizu et al., Jpn. J. Appl. Phys. 44, No. (8), 2005, pp. 6131-6135 (which is incorporated herein by reference). In general, the film thickness may be determined by an atomic force microscope (AFM), a transmission electron microscope (TEM), or the like, which is used preliminarily or together with the X-ray reflectivity measurement method according to the present invention. In other words, a film thickness determined by the AFM and/or the TEM is used to be matched with a film thickness determined by the grazing incident X-ray reflectivity measurement method.

According to the present invention, the insulator or the semiconductor is not particularly limited as long as it offers an insulating function or a semiconductive property from the viewpoint of electron conductivity, and Ge or the SiGe compound and the metal, in particular, Ge and the metal are brought into ohmic contact with each other at the above-described portion. Examples of the insulator may include, but are not limited to, oxides, sulfides, nitrides, and compounds thereof. Furthermore, “compounds thereof” may include acid nitrides, sulfuric nitrides, and the like.

The term “ohmic contact” used herein means a following state from the viewpoint of voltage-current characteristics. The term “ohmic contact” used herein means a contact in which a current I_{OFF} in an OFF state at a voltage of −1 V (or 1 V) and a current I_{ON} in an ON state at a voltage of 1 V (or −1 V) based on a Schottky barrier satisfy following Formula A. In contrast, the term “Schottky junction” used herein means a junction in which the currents I_{OFF} and I_{ON} defined above satisfy following Formula B.

0.1≦|I_{OFF}|/|I_{ON}|≦1 (Formula A)

|I_{OFF}|/|I_{ON}|<0.1 (Formula B)

For a better understanding, the terms “ohmic contact” and “Schottky junction” used herein will be explained with reference to FIG. 1. FIG. 1 is a graph generally illustrating the terms “ohmic contact” and “Schottky junction” used herein.

In voltage-current characteristics indicated by “Δ”, a current is substantially directly proportional to a voltage, wherein |I_{OFF,1}|/|I_{ON,1}| is about 1, thereby to satisfy the Formula A, showing that this case indicates the “ohmic contact” according to the present invention.

Alternatively, in voltage-current characteristics indicated by “•”, |I_{OFF,2}|/|I_{ON,2}| is about 0.5, thereby to satisfy the Formula A, showing that this case indicates the “ohmic contact” according to the present invention.

In contrast, since voltage-current characteristics indicated by “X” indicate the “Schottky junction”, |I_{OFF,3}|/|I_{ON,3}| is about 0.05 or less, which satisfies not the Formula A but the Formula B. This case is encompassed in not the “ohmic contact” but the “Schottky junction” according to the present invention.

A device according to the present invention is applicable to various kinds of semiconductor devices. Specifically, it may be applied to a semiconductor device in which n type Ge and a metal are brought into ohmic contact with each other; a semiconductor device in which p type Ge and a metal are brought into Schottky junction with each other; an n-channel transistor using p type Ge; and the like, but it is not limited thereto. Examples of the n-channel transistor using p type Ge may include, but is not limited to, an n-MOSFET(1) having configuration illustrated in FIG. 4. In FIG. 4, a metal Al, p type Ge, and an insulator GeOₓ having a predetermined film thickness or the like according to the present invention interposed therebetween form the portion consisting of i) the substance, ii) the metal, and iii) the insulator, according to the present invention.

The above-described semiconductor device may be manufactured by the method comprising the steps of:

a) preparing i) the substance;

b) arranging iii) the substance directly on a surface of i) the substance; and

c) arranging ii) the metal directly on a surface of iii) the substance.

Furthermore, reference numbers i) to iii) refer to the same terms i) to iii) described above. That is to say, i) means “Ge or the SiGe compound,” in particular, “Ge”; ii) means “the metal”; and iii) means the insulator or the semiconductor arranged between i) the substance and ii) the metal, in particular, the semiconductor. Therefore, i) the Ge or the SiGe compound, ii) the metal, and iii) the insulator, each having the characteristics in the above-described semiconductor device, may be used.

Furthermore, the semiconductor device according to the present invention may be obtained in steps reverse to the steps a) to c), that is, x) preparing a metal; y) arranging an insulator or a semiconductor (in particular, an insulator) directly on a surface of the metal; and z) arranging Ge or an SiGe compound (in particular, Ge) on a surface of the insulator or the semiconductor.

The step a) is a step of preparing Ge or an SiGe compound (preferably Ge). In order to remove impurities present on a surface of the Ge or a surface of the SiGe compound, the step a) may further comprise a step of cleaning the surface of Ge or the SiGe compound.

The step b) is a step of arranging an insulator or semiconductor directly on a surface of the Ge or SiGe compound. The insulator or semiconductor may be arranged by various conventional techniques. For example, the insulator or the semiconductor may be arranged directly on a surface of the Ge or the SiGe compound by various kinds of sputtering, vacuum deposition, heat treatment in oxygen after the metal or the semiconductor is deposited, and the like. In the technique used herein, the film thickness of the insulator can be controlled by setting various conditions such as time.

The step c) is a step of arranging the metal directly on a surface of the resultant insulator or semiconductor. The metal is arranged by conventionally known various techniques.

Hereinafter, the present invention will be described in more detail by way of examples, but is not limited thereto.

### Example 1

### N type Ge—Al₂O₃—Au, Thickness of Al₂O₃: 0.3 nm

An n type Ge (100) substrate was cleaned with methanol, HCl, H₂O₂—NH₄ and HF.

Al₂O₃ was deposited on a surface of the resultant n type Ge at room temperature by RF sputtering. Thereafter, the resultant deposit was annealed at 400° C. in the presence of nitrogen.

The film thickness of Al₂O₃ was observed to be 0.3 nm from the sputtering time, and from results of measurement by a grazing incident X-ray reflectivity measurement method (SLX 2000 manufactured by RIGAKU Co., Ltd.).

Further, no increase in surface roughness caused by the deposition of Al₂O₃ was found by observing the surface roughness of n type Ge and Al₂O₃ by AFM (D-3000 manufactured by DI Co., Ltd.) (the surface roughness rms of Ge was 0.35 nm; and the surface roughness rms of Al₂O₃ was 0.37 nm).

An Au electrode (having a radius of 200 μm and a thickness of 50 nm) was deposited on the side of Al₂O₃ of the resultant n type Ge—Al₂O₃.

J-V characteristics were examined on the resultant n type Ge—Al₂O₃—Au. The results are shown in FIG. 3. In FIG. 3, a vertical axis logarithmically indicates a current density (A/cm²) whereas a lateral axis indicates a voltage (V). Furthermore, a negative current is logarithmically indicated as a positive current.

FIG. 3 shows that an n type Ge—Al₂O₃—Au according to Example 1 achieves an ohmic contact.

### Examples 2 and 3

### N type Ge—Al₂O₃—Au, Thickness of Al₂O₃: 0.6 nm (Example 2) and 1.3 nm (Example 3)

An n type Ge—Al₂O₃—Au was prepared in a manner similar to Example 1 except that an RF sputtering time was varied, and further, the thickness of Al₂O₃ was set to 0.6 nm (in Example 2) or 1.3 nm (in Example 3). The results are shown in FIG. 3.

FIG. 3 shows that n type Ge—Al₂O₃—Au in Examples 2 and 3 achieve an ohmic contact, as in Example 1,

### Comparative Example 1

### N Type Ge—Au

An n type Ge (100) substrate was cleaned with methanol, HCl, H₂O₂—NH₄ and HF.

An Au electrode (having a radius of 200 μm and a thickness of 50 nm) was deposited on a surface of n type Ge.

J-V characteristics were examined on the resultant n type Ge—Au. The results are shown by “w/o” in FIG. 3.

FIG. 3 shows that an n type Ge—Au according to Comparative Example 1 achieves a Schottky junction.

In contrast, as described above, it is found that an n type Ge—Al₂O₃—Au, each having the specified thickness of Al₂O₃ in Examples 1 to 3, achieves the ohmic contact.

### Examples 4 to 6

### P type Ge—Al₂O₃—Au, Thickness of Al₂O₃: 0.3 nm (Example 4), 0.6 nm (Example 5), and 1.3 nm (Example 6)

A p type Ge—Al₂O₃—Au was prepared in a manner similar to Example 1, except that the type used of Ge was varied from n to p, that an RF sputtering time was varied, and that the thickness of Al₂O₃ was set to 0.3 nm (Example 4), 0.6 nm (Example 5), or 1.3 nm (Example 6). The results are shown in FIG. 4.

FIG. 4 shows that p type Ge—Al₂O₃—Au according to Examples 4 to 6 achieve a Schottky junction between p type Ge and Au.

### Comparative Example 2

### P type Ge—Au

A p type Ge—Au was prepared in a manner similar to Comparative Example 1, except that the type used of Ge was varied from n to p. J-V characteristics were examined on the resultant p type Ge—Au. The results are shown by “w/o” in FIG. 4.

FIG. 4 shows that a p type Ge—Au according to Comparative Example 2 achieves an ohmic contact. In contrast, as described above, it is found that a p type Ge—Al₂O₃—Au, each having the specified thickness of Al₂O₃ in Examples 4 to 6, achieves the Schottky junction between p type Ge and Au.

### N type Ge—Al₂O₃—Al

### Example 7

An n type Ge—Al₂O₃—Al was prepared in a manner similar to Example 1, except that an Au electrode was replaced with an Al electrode (the thickness of Al₂O₃: 0.6 nm). The results are shown in FIG. 5.

FIG. 5 shows that an n type Ge—Al₂O₃—Al according to Example 7 achieves an ohmic contact, as in Example 1.

### N type Ge—Al> and <n Type Ge—Al₂O₃ (Having Film Thickness Which Produces No Desired Characteristics)—Al

### Comparative Example 3

An n type Ge—Al was obtained in a manner similar to Comparative Example 1, except that an Al electrode in place of an Au electrode was thermally deposited on a surface of the n type Ge. J-V characteristics were examined on the resultant n type Ge—Al. The results are shown by “w/o” and “□” in FIG. 5.

FIG. 5 shows that an n type Ge—Al according to Comparative Example 3 achieves a Schottky junction.

### N Type Ge—Al₂O₃ (Having Film Thickness which Produces No Desired Characteristics)—Al

### Comparative Example 4

An n type Ge—Al₂O₃—Al was prepared in a manner similar to Example 7, except that Al₂O₃ has a thickness of up to 0.1 nm. J-V characteristics were examined on the resultant n type Ge—Al₂O₃—Al. The results are shown by “up to 0.1 nm” and “•” in FIG. 5.

FIG. 5 shows that an n type Ge—Al₂O₃—Al according to Comparative Example 4 achieves a Schottky junction.

From the results of Example 7, and Comparative Examples 3 and 4, in a case where Al₂O₃ has the specified thickness, specifically, 0.6 nm (Example 7), an n type Ge and Al achieve the ohmic contact. In contrast, in a case where there is no Al₂O₃ (Comparative Example 3) or the thickness of Al₂O₃ is insufficient (Comparative Example 4), an n type Ge and Al achieve the Schottky junction. Furthermore, the thickness of Al₂O₃ in Comparative Example 4 (i.e., up to 0.1 nm) was substantially a measurement limit, and further, the entire surface of the sample was not covered with Al₂O₃.

### N type Ge—GeOₓ—Au>

### Example 8

An n type Ge—GeOₓ—Au was prepared in a manner similar to Example 1, except that GeOₓ (the thickness of GeOₓ: 2.2 nm) was deposited in place of Al₂O₃. J-V characteristics were examined in a manner similar to Example 1. The results are shown in FIG. 6.

FIG. 6 shows that an n type Ge—GeOₓ—Au according to Example 8 achieves an ohmic contact, as in Example 1. Furthermore, FIG. 6 also shows the result of an n type Ge—Au according to Comparative Example 1 (as “w/o” and “▪”). Upon comparison of the results, in a case where GeOₓ having the specified thickness exists, specifically, GeOₓ has a thickness of 2.2 nm (Example 8), an n type Ge and Au achieve the ohmic contact. In contrast, in a case where there is no GeOₓ (Comparative Example 1, as shown by “w/o” in FIG. 6), n type Ge and Au achieve the Schottky junction.

### N type Ge—GeOₓ—Al

### Example 9

An n type Ge—GeOₓ—Al (the thickness of GeOₓ: 1.6 nm) was prepared in a manner similar to Example 8, except that an Au electrode was replaced with an Al electrode. J-V characteristics were examined in a manner similar to Example 1. The results are shown in FIG. 7. Furthermore, FIG. 7 also shows the result of an n type Ge—Al according to Comparative Example 3 (as “w/o” and “▪”).

Upon comparison of the results, in a case where GeOₓ having the specified thickness exists, specifically, GeOₓ has a thickness of 1.6 nm (Example 9), n type Ge and Al achieve the ohmic contact. In contrast, in a case where there is no GeOₓ (Comparative Example 3, as shown by “w/o” in FIG. 7), an n type Ge and Al achieve the Schottky junction.

### N-MOSFET Using p Type Ge as Substrate

### Example 10

A semiconductor device comprising a configuration shown at an upper left portion of FIG. 8 was prepared. Furthermore, the configuration shown at the upper left portion of FIG. 8 is identical to that shown in FIG. 2. Specifically, a GeOₓ film having about 2 nm was formed on a p type Ge substrate, and further, Al was deposited on the GeOₓ film. Thereafter, Al was served as an electrode by patterning or the like. And then, GeO₂ serving as a gate insulating film was deposited. Finally, a gate electrode Au was formed, thereby to obtain an MOSFET structure.

It was found that the resultant semiconductor device exhibited an n-MOSFET function. FIG. 8 shows Is-Vds characteristics, and shows that the resultant semiconductor device exhibited an n-MOSFET function. This result was achieved as follows: a GeO₂ side of p type Ge became a inversion layer by applying a gate voltage, thereby to provide an “n type Ge” state, wherein the “n type Ge” state, the insulating film GeOₓ, and the metal Al form the portion according to the present invention in an ohmic contact with each other: in contrast, “p type Ge”, the insulating film GeOₓ, and the metal Al form the portion according to the present invention in a Schottky junction on a bulk side of p type Ge.

### BRIEF DESCRIPTION OF DRAWINGS

FIG. 1 is a graph schematically explaining the terms “ohmic contact” and/or “Schottky junction” according to the present invention.

FIG. 2 is a view schematically showing an n-MOSFET using p type Ge as a substrate in one aspect of the present invention.

FIG. 3 is a graph illustrating an ohmic contact in a configuration of n type Ge—Al₂O₃—Au in Examples 1 to 3.

FIG. 4 is a graph illustrating an ohmic contact in a configuration of p type Ge—Al₂O₃—Au in Examples 4 to 6.

FIG. 5 is a graph illustrating an ohmic contact in a configuration of n type Ge—Al₂O₃—Al in Example 7.

FIG. 6 is a graph illustrating an ohmic contact in a configuration of n type Ge—GeOₓ—Au in Example 8.

FIG. 7 is a graph illustrating an ohmic contact in a configuration of n type Ge—GeOₓ—Al in Example 9.

FIG. 8 is a graph illustrating a configuration of “an n-MOSFET using p type GE as a substrate” and its result (i.e., a function of the n-MOSFET) in Example 10.

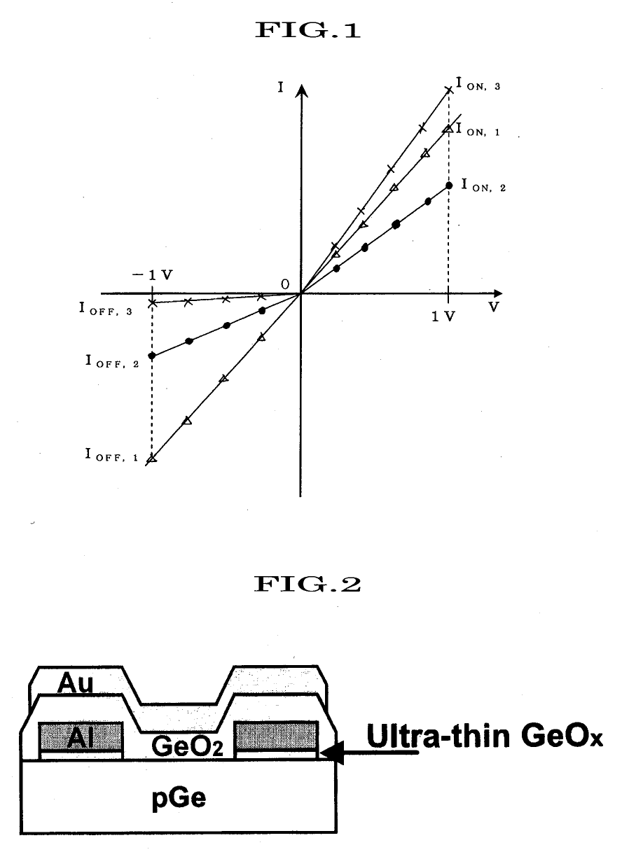

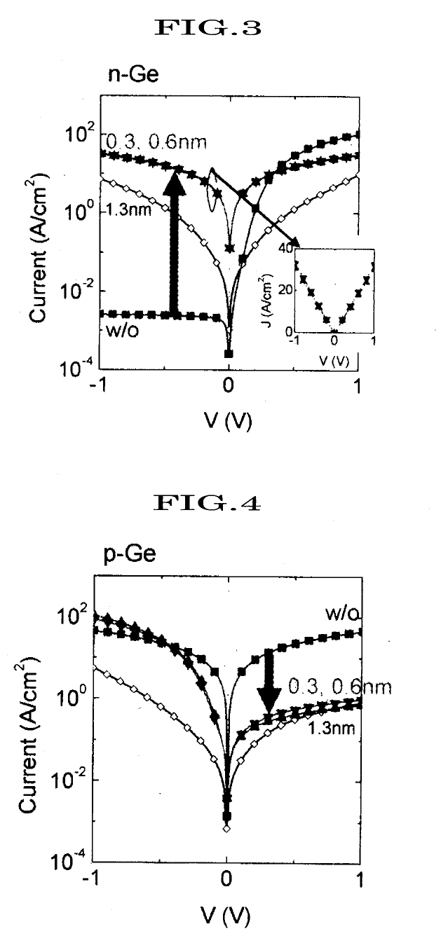

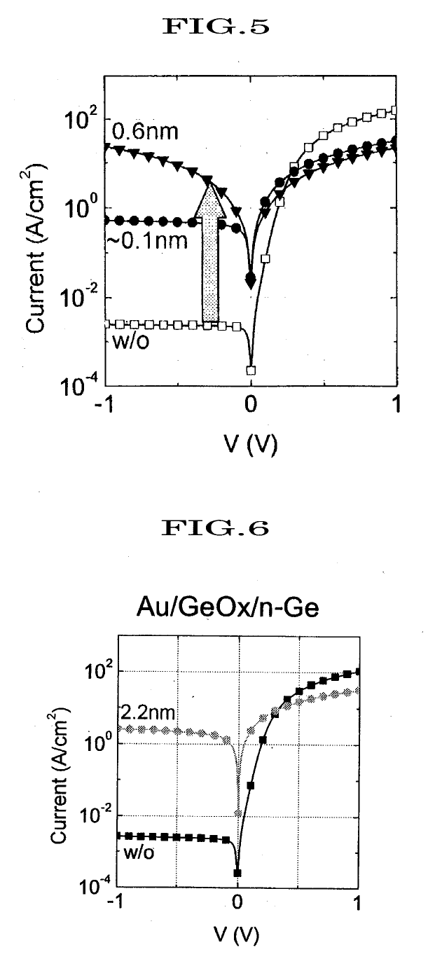

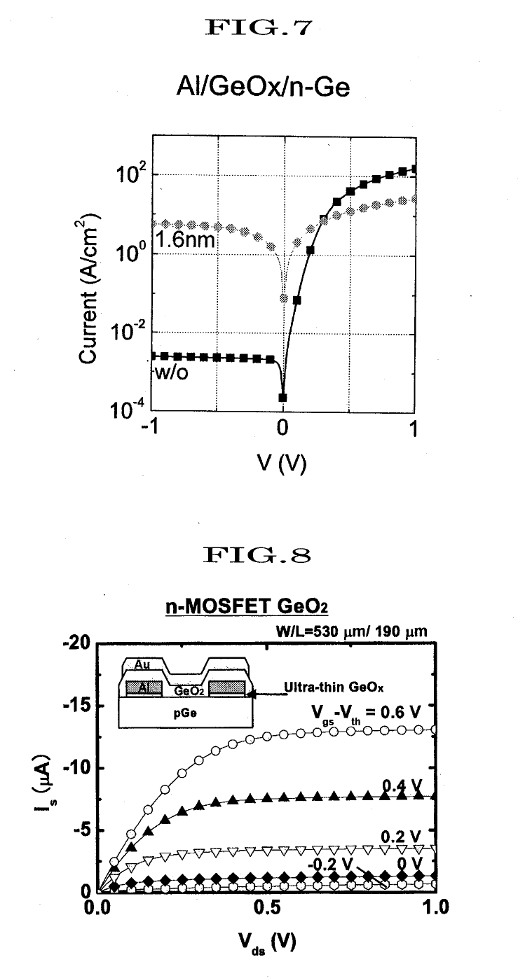

1. A semiconductor device comprising a portion consisting of i) Ge or an SiGe compound; ii) a metal; and iii) an insulator or a semiconductor arranged between i) the substance and ii) the metal,
wherein A) in a case where holes of i) the substance are majority carriers, i) the substance and ii) the metal have a Schottky junction; and/or
B) in a case where B) electrons of i) the substance are majority carriers, i) the substance and ii) the metal are brought into ohmic contact with each other.

2. The device according to claim 1, wherein iii) the substance is an insulator having a thickness of 2.5 nm or less.

3. A semiconductor device comprising a portion consisting of i) Ge or an SiGe compound; ii) a metal; and iii′) an insulator arranged between i) the substance and ii) the metal, iii′) the insulator having a thickness of 2.5 nm or less.

4. The device according to claim 1, wherein i) the substance is Ge.

5. The device according to claim 1, wherein the insulator is selected from the group consisting of oxides, nitrides, sulfides, and compounds thereof.

6. A method for manufacturing a semiconductor device, the semiconductor device comprising a portion consisting of i) Ge or an SiGe compound; ii) a metal; and iii) an insulator or a semiconductor arranged between i) the substance and ii) the metal,
wherein A) in a case where holes of i) the substance are majority carriers, i) the substance and ii) the metal have a Schottky junction; and/or
B) in a case where B) electrons of i) the substance are majority carriers, i) the substance and ii) the metal are brought into ohmic contact with each other,
the method comprising the steps of:
a) preparing i) the substance;
b) arranging iii) the substance directly on a surface of i) the substance; and
c) arranging ii) the metal directly on a surface of iii) the substance.

7. A method for manufacturing a semiconductor device, the semiconductor device comprising a portion consisting of i) Ge or an SiGe compound; ii) a metal; and iii′) an insulator arranged between i) the substance and ii) the metal, iii′) the insulator having a thickness of 2.5 nm or less, the method comprising the steps of:
a) preparing i) the substance;
b) arranging iii′) the insulator directly on a surface of i) the substance; and
c) arranging ii) the metal directly on a surface of iii′) the insulator.

8. The device according to claim 3, wherein i) the substance is Ge.

9. The device according to claim 3, wherein the insulator is selected from the group consisting of oxides, nitrides, sulfides, and compounds thereof.
